(19) United States
(12) Patent Application Publication
(10) Pub. No.: US 2024/0276863 A1
(43) Pub. Date: Aug. 15, 2024

(54) ELEMENT USING CARBON NANOTUBE FILM, A BOLOMETER USING THE SAME AND A METHOD FOR MANUFACTURING THE SAME

(71) Applicant: NEC Corporation, Tokyo (JP)

(72) Inventors: Tomo TANAKA, Tokyo (JP); Toshie MIYAMOTO, Tokyo (JP)

(73) Assignee: NEC Corporation, Tokyo (JP)

(21) Appl. No.: 18/426,804

(22) Filed: Jan. 30, 2024

(30) Foreign Application Priority Data
Feb. 14, 2023 (JP) 2023-020406

(51) Int. Cl. H10K 85/20; B82Y 30/00; H10K 30/81; H10K 71/60; G01J 5/20

(52) U.S. Cl. CPC H10K 85/221; B82Y 30/00; H10K 30/81; H10K 71/60; G01J 5/20

(57) ABSTRACT

The present invention provides a carbon nanotube element comprising: a multi-layered structure in which a plurality of carbon nanotube films and one or more insulating film(s) are stacked so that the insulating film(s) insulates between the carbon nanotube films, and a first electrode and a second electrode arranged with a distance, wherein each carbon nanotube film in the multi-layered structure is electrically connected to the first electrode and the second electrode, and the carbon nanotube films are connected in parallel to each other between the first electrode and the second electrode. The carbon nanotube element has reduced resistance while using a semiconductor carbon nanotube film, and is suitable for a bolometer.

This application is based upon and claims the benefit of priority from Japanese patent application No. 2023-020406, filed on Feb. 14, 2023, the disclosure of which is incorporated herein in its entirety by reference.

### TECHNICAL FIELD

The present invention relates to an element using a carbon nanotube film, a bolometer using the same and a method for manufacturing the same.

### BACKGROUND ART

Since the discovery of carbon nanotubes, various applications have been proposed, and in particular, applications have been proposed for semiconducting single-walled carbon nanotubes that take advantage of their semiconducting properties, such as field-effect transistors (FETs) and infrared sensors.

Infrared sensors have a very wide range of applications such as not only monitoring cameras for security, but also thermography for human body, in-vehicle cameras, and inspection of structures, foods, and the like, and are thus actively used in industrial applications in recent years. In particular, development of a low-cost and high-performance uncooled infrared sensor capable of obtaining biological information in cooperation with IoT (Internet of Things) is expected. In conventional uncooled infrared sensors, VOx (vanadium oxide) has been mainly used in the bolometer unit, but the problem thereof is that the process cost is high because heat treatment under vacuum is required and the temperature coefficient resistance (TCR) thereof is low (about −2.0%/K).

In order to improve TCR, a material with large resistance-change vs temperature-change and high conductivity is required. Hence, it is expected to use semiconducting single-walled carbon nanotubes which have large band gap and carrier mobility to the bolometer part. In addition, since carbon nanotubes are chemically stable, an inexpensive device fabrication processes such as printing technology can be used, and thus the realization of low-cost and high-performance infrared sensors is highly expected.

For example, Patent Document 1 proposed to apply typical single-walled carbon nanotubes to a bolometer unit, and produce a bolometer by a low-cost thin film process in which a dispersion liquid is prepared by mixing single-walled carbon nanotubes in an organic solvent utilizing their chemical stability and then is applied on an electrode. In this case, TCR is successfully improved to about −1.8%/K by subjecting single-walled carbon nanotubes to annealing treatment in the air.

Patent Document 2 discloses to apply semiconducting single-walled carbon nanotubes with uniform chirality to the bolometer part, and injecting electrons or holes into the channel part (carbon nanotube) via an ionic liquid to eliminate the effects of various dopants so as to obtain a TCR of −2.6%/K.

Furthermore, Patent Document 3 discloses an infrared sensor in which the TCR was successfully further improved to −3.3%/K or more by using a carbon nanotube film containing semiconducting carbon nanotubes having a predetermined diameter and length.

### CITATION LIST

### Patent Literature

Patent Document 1: WO2012/049801
Patent Document 2: Japanese Patent Laid-Open Publication No. 2015-49207
Patent Document 3: WO2020/158455

### SUMMARY OF INVENTION

### Technical Problem

As described in Patent Documents 1 to 3, in a bolometer using carbon nanotubes as a bolometer film, it is necessary to use semiconducting carbon nanotubes in order to achieve a large TCR (absolute value). On the other hand, it is desirable to lower the resistance of the bolometer film to improve the sensitivity and reduce noise. That is, in order to achieve high sensitivity (low noise) in addition to a large TCR in a bolometer using semiconductor carbon nanotubes, a means for lowering the resistance is required.

In view of the above-mentioned problems, an object of the present invention is to provide an element having a structure capable of reducing resistance using a semiconductor carbon nanotube film, a bolometer using the same, and a method for manufacturing the same.

### Solution to Problem

One aspect of the present invention relates to a carbon nanotube element comprising:
a multi-layered structure in which a plurality of carbon nanotube films and one or more insulating film(s) are stacked so that the insulating film(s) insulates between the carbon nanotube films, and
a first electrode and a second electrode arranged with a distance,
wherein each carbon nanotube film in the multi-layered structure is electrically connected to the first electrode and the second electrode, and the carbon nanotube films are connected in parallel to each other between the first electrode and the second electrode.

Another aspect of the present invention relates to
a method for manufacturing a carbon nanotube element having n-layer carbon nanotube films, the method comprising:
performing following steps (a₁), (b₁) and (c₁) in this order to form a structure having a first layer of carbon nanotube film;
repeating following steps (aₖ), (bₖ) and (cₖ) in this order
   from k=2 to n to form structures having a second layer carbon nanotube film to an n-th layer carbon nanotube film;
(a₁): providing an insulating base material,
(b₁): forming a first branch electrode and a second branch electrode with a distance on the insulating base material provided in step (a₁),
(c₁): forming a carbon nanotube film in contact with the first branch electrode and the second branch electrode formed in step (b1),
(aₖ): forming an insulating film on a first branch electrode, a second branch electrode, and a carbon nanotube film formed in step (bₖ₋₁) and step (cₖ₋₁), respectively,
(bₖ): forming holes in the insulating film formed in step (aₖ) to reach the first branch electrode and the second branch electrode formed in step (bₖ₋₁), and thereafter filling the holes and forming a first branch electrode and a second branch electrode opposing each other with a distance on the insulating film at the same time using an electrode material, and
(cₖ): forming a carbon nanotube film in contact with the first branch electrode and the second branch electrode formed in step (bₖ).

Furthermore, another aspect of the present invention relates to
a method for manufacturing a carbon nanotube element having n-layer carbon nanotube films, the method comprising:
performing following steps (a₁), (c²₁) and (b²₁) in this order to form a structure having a first layer of carbon nanotube film;
repeating following steps (aₖ), (c²ₖ) and (b²ₖ) in this order
   from k=2 to n to form structures having a second layer carbon nanotube film to an n-th layer carbon nanotube film;
(a₁): providing an insulating base material,
(c²₁): forming a carbon nanotube film on the insulating base material provided in step (a₁),
(b²₁): forming a first branch electrode and a second branch electrode with a distance so as to be in contact with the carbon nanotube film formed in step (c²₁),
(aₖ): forming an insulating film on a carbon nanotube film and a first branch electrode and a second branch electrode formed in step (c²ₖ₋₁) and step (b²ₖ₋₁), respectively,
(c²ₖ): forming a carbon nanotube film on the insulating film formed in step (aₖ),
(b²ₖ): forming holes in the insulating film formed in step (aₖ) to reach the first branch electrode and the second branch electrode formed in step (b²ₖ₋₁), and thereafter filling the holes and forming a first branch electrode and a second branch electrode opposing each other with a distance so as to be in contact with the carbon nanotube film formed in step (c²ₖ) at the same time using an electrode material.

### Advantageous Effect of Invention

According to the present invention, provided are an element having a structure capable of reducing resistance using a semiconductor carbon nanotube film, a bolometer using the same, and a method for manufacturing the same.

### BRIEF DESCRIPTION OF DRAWINGS

FIG. 1 is a schematic cross-sectional view of a carbon nanotube element according to an embodiment of the present invention.

FIG. 2 is a schematic cross-sectional view of a process in manufacturing a carbon nanotube element according to an embodiment of the present invention.

FIG. 3 is a schematic cross-sectional view of a process in manufacturing a carbon nanotube element according to an embodiment of the present invention.

FIG. 4 is a schematic cross-sectional view of a process in manufacturing a carbon nanotube element according to an embodiment of the present invention.

FIG. 5 is a diagram illustrating a manufacturing process of a bolometer element according to an embodiment of the present invention.

FIG. 6 is a diagram illustrating a manufacturing process of a bolometer element according to an embodiment of the present invention.

FIG. 7 is a diagram illustrating a manufacturing process of a bolometer element according to an embodiment of the present invention.

FIG. 8 is a diagram illustrating a manufacturing process of a bolometer element according to an embodiment of the present invention.

FIG. 9 is a diagram illustrating a manufacturing process of a bolometer element according to an embodiment of the present invention.

FIG. 10 is a diagram illustrating a manufacturing process of a bolometer element according to an embodiment of the present invention.

FIG. 11 is a diagram illustrating a manufacturing process of a bolometer element according to an embodiment of the present invention.

FIG. 12 is a diagram illustrating a manufacturing process of a bolometer element according to an embodiment of the present invention.

FIG. 13 is a diagram illustrating a manufacturing process of a bolometer element according to an embodiment of the present invention.

FIG. 14 is a diagram illustrating a manufacturing process of a bolometer element according to an embodiment of the present invention.

FIG. 15 A is a diagram illustrating a manufacturing process of a bolometer element according to an embodiment of the present invention.

FIG. 15 B is a diagram illustrating a manufacturing process of a bolometer element according to an embodiment of the present invention.

FIG. 16 is a diagram illustrating a manufacturing process of a bolometer element according to an embodiment of the present invention.

FIG. 17 A is a diagram illustrating a manufacturing process of a bolometer element according to an embodiment of the present invention.

FIG. 17 B is a diagram illustrating a manufacturing process of a bolometer element according to an embodiment of the present invention.

FIG. 18 is a diagram illustrating a manufacturing process of a bolometer element according to an embodiment of the present invention.

FIG. 19 A is a diagram illustrating a manufacturing process of a bolometer element according to an embodiment of the present invention.

FIG. 19 B is a diagram illustrating a manufacturing process of a bolometer element according to an embodiment of the present invention.

FIG. 20 is a diagram illustrating a manufacturing process of a bolometer element according to an embodiment of the present invention.

FIG. 21 is a perspective view of a bolometer element according to another embodiment of the invention.

FIG. 22 is a schematic cross-sectional view of a bolometer element according to another embodiment of the present invention.

FIG. 23A is a schematic cross-sectional view illustrating a bolometer array.

FIG. 23B is a circuit diagram for explaining a bolometer array.

FIG. 24 is a diagram illustrating a manufacturing process of a bolometer element according to an embodiment of the present invention.

FIG. 25 is a diagram illustrating a manufacturing process of a bolometer element according to an embodiment of the present invention.

FIG. 26 is a diagram illustrating a manufacturing process of a bolometer element according to an embodiment of the present invention.

### DESCRIPTION OF EMBODIMENTS

Embodiments of the present invention will be described in detail below with reference to the drawings.

### <Carbon Nanotube Film>

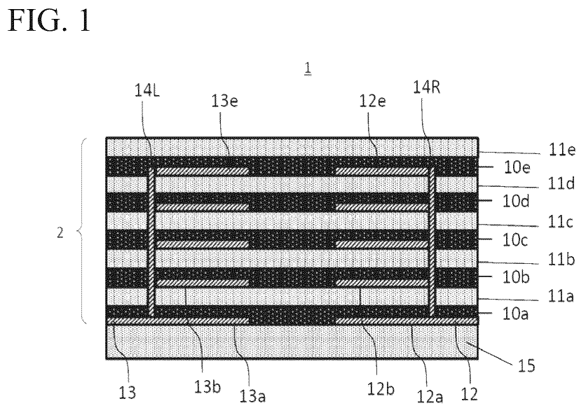

FIG. 1 shows a schematic cross-sectional view of a typical configuration of a carbon nanotube element (hereinafter also referred to as “CNT element”) according to an embodiment of the present invention. In this figure, the vertical size/distance is shown larger than the actual size. This cross-sectional view is not limited to a case where the cutting line is a straight line, but may be a cross-sectional view appearing by a curved or polyline cutting line.

The CNT element 1 has a multi-layered structure 2, a first electrode 12, and a second electrode 13, and is usually formed on the surface of an insulating base material 15. The insulating base material 15 may be an insulating substrate as long as at least the surface on which the multi-layered structure 2 is formed is insulating. Examples thereof include an insulating substrate, a semiconductor substrate or a metal substrate having an insulating film formed on the surface thereof. For example, a silicon substrate on which an insulating film such as a silicon oxide film is formed may be used. The term “insulating base material” here means something that supports a multi-layered structure, and the entire semiconductor substrate or metal substrate with an insulating film formed on the surface may be regarded as an insulating base material, or the insulating film may be regarded as an insulating base material. The term “insulating base material” also includes members that do not have enough strength to support the entire device, such as the diaphragm portion described in Embodiment 2.

The multi-layered structure 2 has a structure in which a plurality of semiconducting carbon nanotube films (10a to 10e; hereinafter also referred to as “CNT films”) and a plurality of insulating films (11a to 11d) provided therebetween are alternately laminated. These insulating films insulate the upper and lower CNT films sandwiching the insulating film. Although FIG. 1 shows a form in which an insulating film 11e is also formed on the uppermost CNT film, the insulating film 11e is not an essential element. However, it is preferable to exist for other purposes (for example, a protective film, a light absorption film, etc.), and in that case, the material thereof may be different and also the thickness thereof may be largely different from those of the inner layer insulating film (11a to 11d). Also regarding the inner layer insulating films (11a to 11d), although they may have different materials and thicknesses, it is usually easier to manufacture them from the same material and manufacture them to have substantially the same thickness. Examples of the material for the insulating film include a silicon oxide film, a silicon nitride film, and other materials which will be described later in Embodiment 1 of the bolometer as materials for insulating films, protective films, or heat insulating layers.

The CNT films (10a to 10e) in the stacked structure 2 are connected to the first electrode 12 and the second electrode 13, in which the CNT films (10a to 10e) are connected in parallel, i.e. electrical parallel connection. Specifically, the first electrode 12 and the second electrode 13 each have a plurality of first branch electrodes (12a to 12e) and a plurality of second branch electrodes (13a to 13e), and each CNT film is electrically connected to a first branch electrode (one of 12a to 12e) and a second branch electrode (one of 13a to 13e) which is disposed with a distance from the first branch electrode. The first branch electrodes (12a to 12e) are electrically connected to each other by a connection electrode 14R, and together constitute the first electrode 12, and similarly, the second branch electrodes (13a to 13e) are electrically connected to each other by a connection electrode 14L, and together constitute the second electrode 13. When a voltage is applied between the first electrode 12 and the second electrode 13, current flows through the CNT film existing between the first branch electrode and the second branch electrode, so various devices can be configured using the function of the CNT film.

Here, the branch electrodes are the branched parts of the first electrode and the second electrode. The part where the branch electrodes merge (the part that is combined into one; the base part) may also be a part of the wiring that is connected to the circuit. While FIG. 1 shows an example in which the CNT film has five layers, it may be at least two layers or more. Taking into consideration various factors such as the characteristics, structure, element design, and productivity of the intended device, the optimal number of layers can be selected.

The first electrode 12 and the second electrode 13 and their respective branch electrodes, connection electrodes, and the like can be formed using known electrode materials, for example, gold, platinum, titanium, or combination of two or more of these.

In the CNT element of the present embodiment, since the CNT films in the stacked structure are connected in parallel, the resistance of the entire element can be reduced. Therefore, by using the CNT element of the present embodiment in the light receiving part of a bolometer, it is possible to configure a bolometer film with low resistance, and therefore the sensitivity of the bolometer can be improved and noise can be reduced.

As a method for lowering the resistance of a bolometer film other than the present invention, it may be conceivable to shorten the length of the carbon nanotube film, that is, the distance between the electrodes. However, in a carbon nanotube film containing metallic carbon nanotubes, a path of metallic carbon nanotubes is formed, leading to decrease in TCR. It is also conceivable to widen the width of the carbon nanotube film. However, this increases the pixel size, which hinders increasing the degree of integration. Furthermore, when the thickness of the carbon nanotube film is increased, the number of carbon nanotubes that do not contact the contact electrode increases, and the effective resistance value may increase. If dispersion (i.e. deposition) of carbon nanotubes and electrode formation are performed alternately, the problem of contact with the electrode can be solved. However, since photolithography must be repeated, detachment of carbon nanotubes may take place and/or opportunities of contact with chemicals increases. This may cause a problem of deterioration of characteristics due to doping, increase in defects, and the like.

However, in the bolometer using the element of the present embodiment, it is possible to lower the resistance without excessively changing the size or thickness of the carbon nanotube film. This makes it possible to improve sensitivity and reduce noise of the bolometer while maintaining the TCR and footprint size of the bolometer.

### <Manufacturing Method of CNT Element>

Although the CNT element having the structure shown in FIG. 1 can be manufactured by various methods, a typical manufacturing method will be described. Herein, formation and patterning of films (layers) made of each material can be performed using known deposition methods, photolithography methods, etching methods, and the like, and thus the details thereof will be omitted.

### <Manufacturing Method 1>

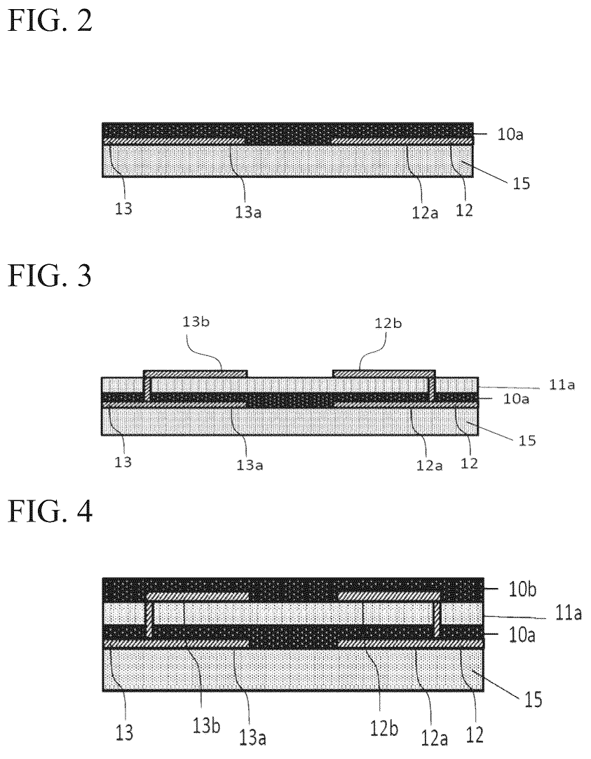

First, as shown in FIG. 2, an insulating base material 15 is provided in a step (a₁), and a first branch electrode 12a and a second branch electrode 13a are formed on the insulating base material in a step (b1). The first branch electrode 12a and the second branch electrode 13a are spaced with predetermined distance in the parallel direction of the insulating base material 15. Thereafter, in step (c 1), the carbon nanotube film 10a is formed so as to be in contact with the first branch electrode 12a and the second branch electrode 13a. As a result, a structure having one layer of CNT film shown in FIG. 2 is formed.

Next, a second layer structure is formed as follows.

In step (a₂), an insulating film 11a is formed on the first branch electrode 12a, the second branch electrode 13a, and the carbon nanotube film 10a formed in step (b₁) and step (c₁), respectively. Usually, the insulating film is formed on the entire surface of the base material.

In step (b₂), holes are formed in the insulating film 11a formed in step (a₂). The holes have depth to reach the first branch electrode 12a and second branch electrode 13a formed in step (b₁). Then the holes are filled with an electrode material and at the same time, a first branch electrode 12b and a second branch electrode 13b are formed on the insulating film 11a. The first branch electrode 12b and the second branch electrode 13b are likewise spaced with predetermined distance. The first branch electrode 12b and the second branch electrode 13b are electrically connected to the first branch electrode 12a and the second branch electrode 13a, respectively. Through the steps up to this point, the structure shown in FIG. 3 is formed.

Thereafter, in step (c₂), a carbon nanotube film 10b is formed in contact with the first branch electrode 12b and second branch electrode 13b formed in step (b₂). This completes the CNT element shown in FIG. 4, in which two layers of CNT films are electrically connected in parallel.

This process can be generalized as follows.
(aₖ): forming an insulating film on a first branch electrode, a second branch electrode, and a carbon nanotube film formed in step (bₖ₋₁) and step (cₖ₋₁), respectively,
(bₖ): forming holes in the insulating film formed in step (aₖ) to reach the first branch electrode and the second branch electrode formed in step (bₖ₋₁), and thereafter filling the holes and forming a first branch electrode and a second branch electrode opposing each other with a distance on the insulating film at the same time using an electrode material
(cₖ): forming a carbon nanotube film in contact with the first branch electrode and the second branch electrode formed in step (bₖ).

Therefore, a CNT element in which n layers of CNT films are electrically connected in parallel is produced by firstly carrying out the above steps (a₁), (b₁) and (c₁), and repeating (aₖ), (bₖ) and (cₖ) from k=2 to n. For example, a CNT element in which five layers of CNT films are connected in parallel can be manufactured by repeating steps (aₖ), (bₖ) and (cₖ) from k=2 to 5. If necessary, by forming an insulating film 11e, the CNT element shown in FIG. 1 can be completed. In the above manufacturing method, the connection electrodes 14R and 14L in FIG. 1 are formed by stacking of the electrode materials in the holes in step (bₖ) (k=2 to n).

### <Manufacturing Method 2>

In the above manufacturing method 1, an example was shown in which the carbon nanotube film is formed after forming the first branch electrode and the second branch electrode, but after forming the carbon nanotube film, the first branch electrode and the second branch electrode may also be formed.

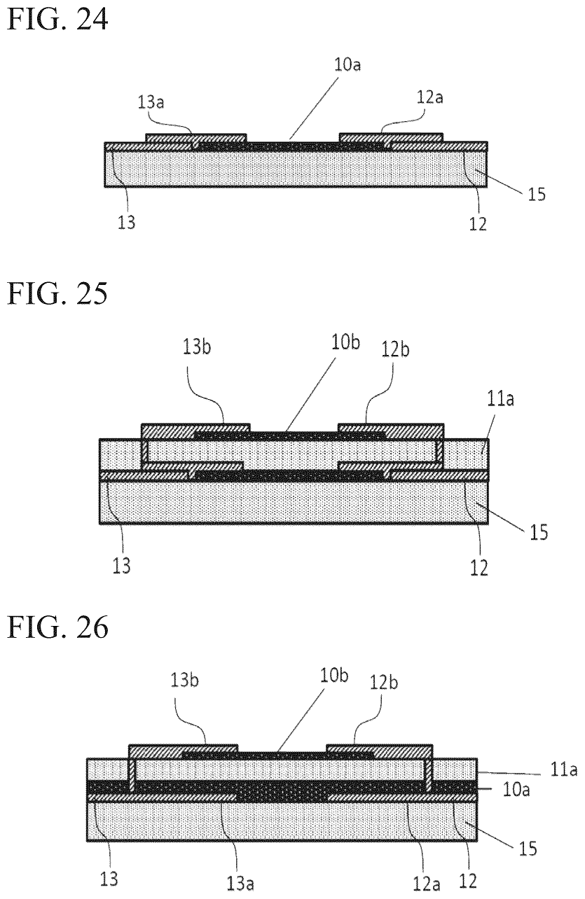

For example, as shown in FIG. 24, the order of step (b₁) and step (c₁) in manufacturing method 1 may be reversed, and performed in the order shown below:
(a₁): providing an insulating base material 15,
(c²₁): forming a carbon nanotube film 10a on the insulating base material provided in step (a₁),
(b²₁): forming a first branch electrode 12a and a second branch electrode 13a with a distance so as to be in contact with the carbon nanotube film formed in step (c²₁),
   The first branch electrode 12a and the second branch electrode 13a are those generally called contact electrodes.

Similarly, for the second and higher layers, the steps can be carried out in the following order.

(aₖ): forming an insulating film on a carbon nanotube film and a first branch electrode and a second branch electrode formed in step (c²ₖ₋₁) and step (b²ₖ₋₁), respectively,

(c²ₖ): forming a carbon nanotube film on the insulating film formed in step (aₖ),

(b²ₖ): forming holes in the insulating film formed in step (aₖ) to reach the first branch electrode and the second branch electrode formed in step (b²ₖ₋₁), and thereafter filling the holes and forming a first branch electrode and a second branch electrode opposing each other with a distance so as to be in contact with the carbon nanotube film formed in step (c²ₖ) at the same time using an electrode material.

In addition, in step (b²ₖ), the sub-step “forming holes in the insulating film formed in step (aₖ) to reach the first branch electrode and the second branch electrode formed in step (b²ₖ₋₁)” can also be performed at the beginning of the step (c²ₖ), before forming the carbon nanotube film.

FIG. 25 shows a diagram showing the formation of up to the second layer continuing from FIG. 24. That is, in step (a₂), an insulating film 11a is formed on the first branch electrode 12a, second branch electrode 13a, and carbon nanotube film 10a formed in step (b²₁) and step (c²₁), respectively. Thereafter, in step (c²₂), a carbon nanotube film 10b is formed on the insulating film 11a. Thereafter, in step (b²₂), holes are formed in the insulating film 11a to reach the first branch electrode 12a and the second branch electrode 13a formed in the step (b₂₁), and then the holes are filled with an electrode material, and at the same time, a first branch electrode 12b and a second branch electrode 13b are formed with distance so as to be in contact with the carbon nanotube film 10b formed in step (c²₂).

In this manner, a CNT element in which n-layer CNT films are electrically connected in parallel is manufactured by repeating the above steps (aₖ), (c²ₖ), and (b²ₖ) from k=2 to n after the steps of (a₁), (c²₁) and (b²₁).

Furthermore, it is also possible to change the order of forming the CNT film and forming the first branch electrode and the second branch electrode in different layers. In the example shown in FIG. 26, the first branch electrode and the second branch electrode are formed first in the first layer, but the CNT film is formed first in the second layer.

A bolometer using the CNT element of the present embodiment as a bolometer film (light receiving section) will be described below. In the content of the explanation of the bolometer, the part that describes the CNT element is not limited to the use as a bolometer, but can be applied to other uses as well.

### Embodiment 1

An example in which a CNT element is applied to an integrated bolometer will be explained while showing the manufacturing process. Although four (2×2) bolometer elements are shown in the drawing, a large number of elements can be integrated in the horizontal and vertical directions.

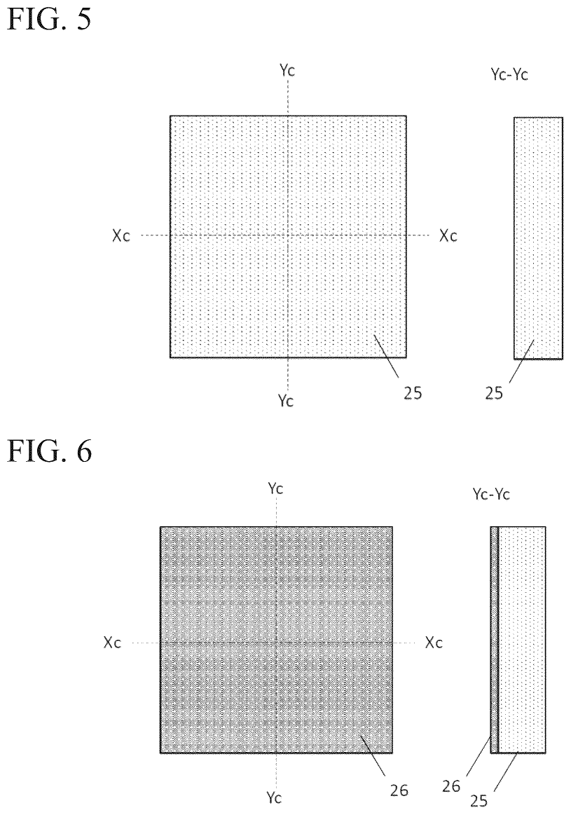

First, as shown in FIG. 5, a silicon substrate is provided as the substrate 25. In the figure, the left side is a plan view, and the one labelled Yc-Yc on the right side shows a Yc-Yc sectional view. Hereinafter in the drawings below, “Xx-Xx” and “Yy-Yy” (x and y are arbitrary symbols) respectively indicate a cross section along Xx-Xx and a cross section along Yy-Yy shown in the plan view.

Examples of substrates include inorganic materials such as Si, SiO₂ coated Si, SiO₂, SiN, and glass, and organic materials such as polymers, resins, and plastics, such as parylene, polyimide, polyethylene, polypropylene, polystyrene, and polystyrene, vinyl chloride, polyethylene terephthalate, acrylonitrile styrene resin, acrylonitrile butadiene styrene resin, fluororesin, methacrylic resin, polycarbonate, and the like can be used, but are not limited to these. Hereinafter, explanation will be made for the case a silicon substrate is used.

Next, as shown in FIG. 6, a silicon oxide film 26 is formed on the surface of the silicon substrate 25 as an insulating film. A heat insulating layer may be formed instead of or in addition to the silicon oxide film. As the heat insulating layer, a resin component with low thermal conductivity can be used. The thermal conductivity of the resin component used for the heat insulating layer is lower than that of the substrate 101, for example, in a range of 0.02 to 0.3 (W/mK), preferably 0.05 to 0.15 (W/mK). Such resin components include, but are not limited to, parylene. Parylene is a generic term for paraxylene-based polymers, and has a structure in which benzene rings are connected via CH₂. Examples of parylene include parylene N, parylene C, parylene D, and parylene HT, among which parylene C (thermal conductivity: 0.084 (W/mK)) is preferred because it has the lowest thermal conductivity.

The thickness of the heat insulating layer can be appropriately set in considering the heat conductivity of the component to use, and in a case of using parylene C for example, it is preferably in the range of 5 μm to 50 μm, and more preferably in the range of 10 μm to 20 μm.

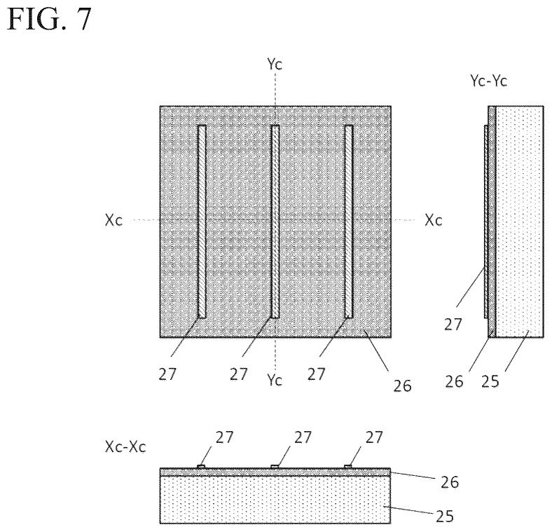

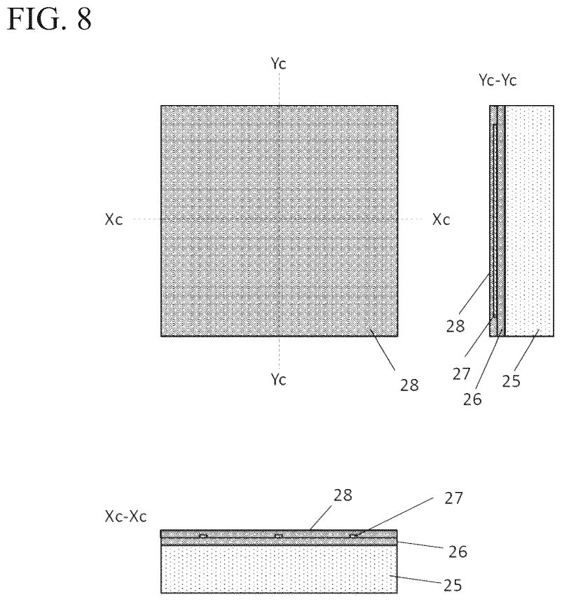

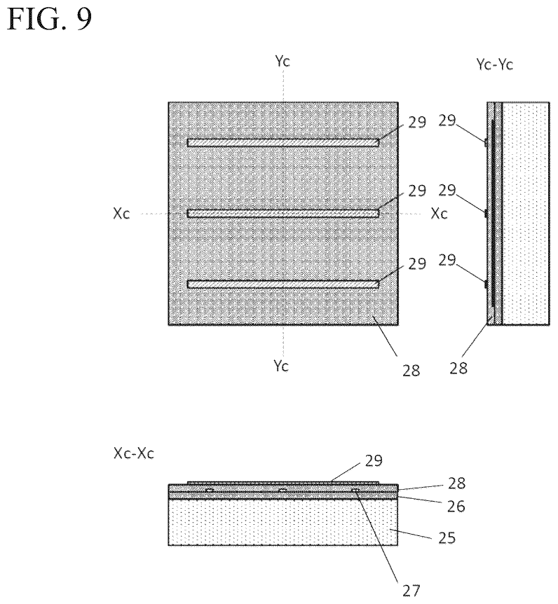

Next, as shown in FIG. 7, a metal wiring such as Ti/Au is formed as a vertical wiring 27 on the surface of the silicon oxide film 26 by a known method such as vapor deposition. Next, as shown in FIG. 8, a silicon oxide film 28 is formed on the surface, whereby the vertical wirings 27 are embedded. Next, as shown in FIG. 9, a metal wiring such as Ti/Au is formed as a horizontal wiring 29 on the surface of the silicon oxide film 28 by a known method such as vapor deposition. As a material for the wiring, aluminum, gold, copper, tungsten, cobalt, an alloy made of these, a stacked structure using a Ti layer as a lower layer, and the like can be used. Wiring for signal output can be formed by vapor deposition or printing after patterning with a metal mask or the like if necessary.

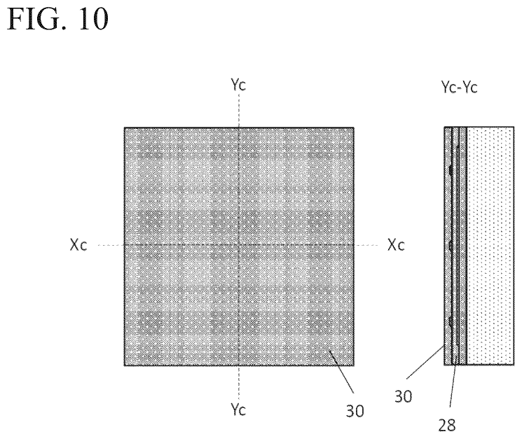

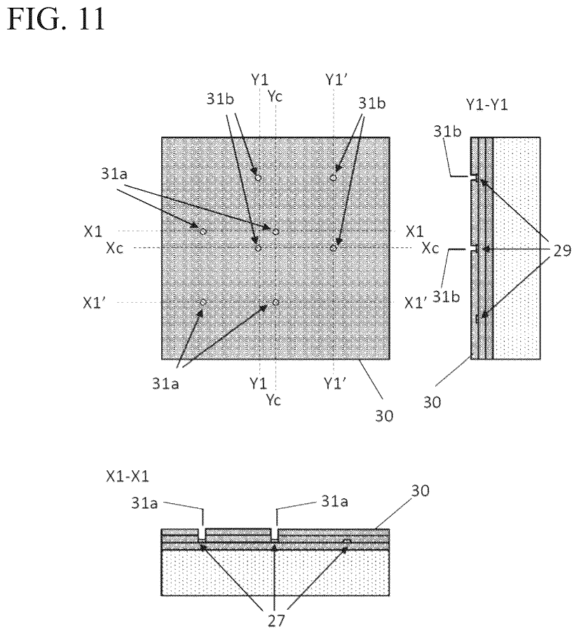

Next, as shown in FIG. 10, a silicon oxide film 30 is formed, whereby the horizontal wirings 29 are embedded. Next, as shown in FIG. 11, the silicon oxide film 30 is etched to form contact holes (eight in FIG. 11). FIG. 11 shows an X1-X1 section (the X1′-X1′ section also has the same shape) and a Y1-Y1 section (the Y1′-Y1′ section also has the same shape) passing through the center of the contact holes as cross-sectional views. The contact holes 31a (four in the figure) are formed as holes that reach the vertical wirings 27 using the vertical wirings 27 as an etching stopper, and the contact holes 31b (four in the figure) are formed as holes that reach the horizontal wirings 29 using the horizontal wirings 29 as an etching stopper.

Examples of methods for forming contact holes include etching (dry etching, wet etching, and the like) and mechanical removal (dicing, drilling, and the like). From the viewpoint of processing precision, dry etching, particularly anisotropic dry etching such as reactive ion etching (RIE), is preferable.

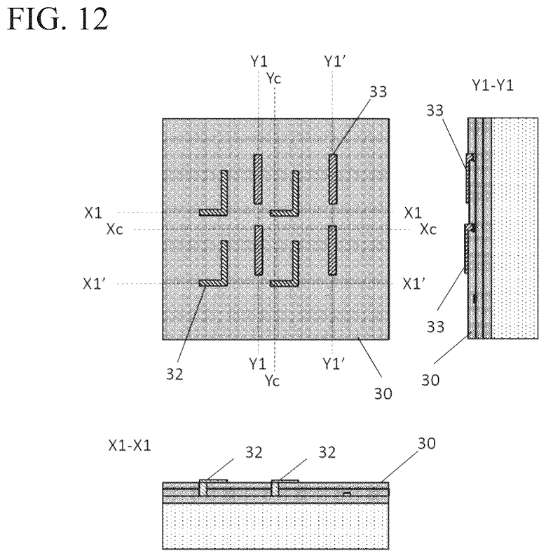

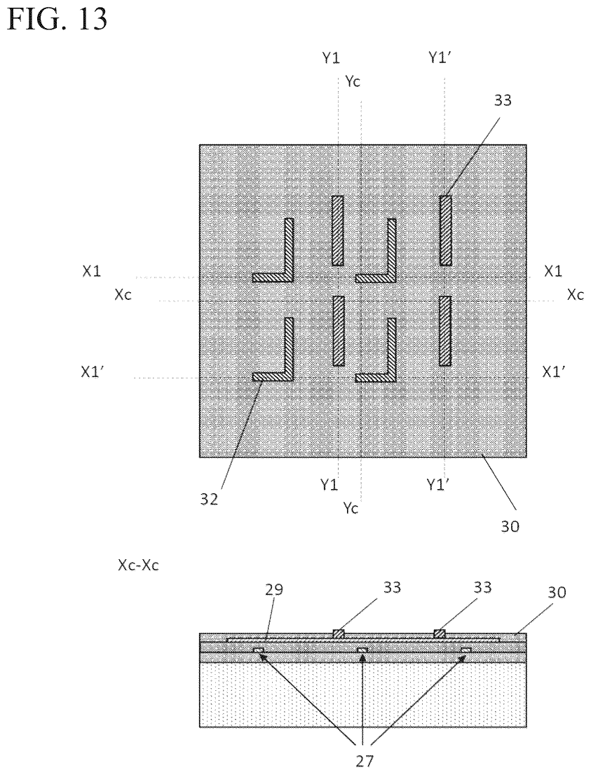

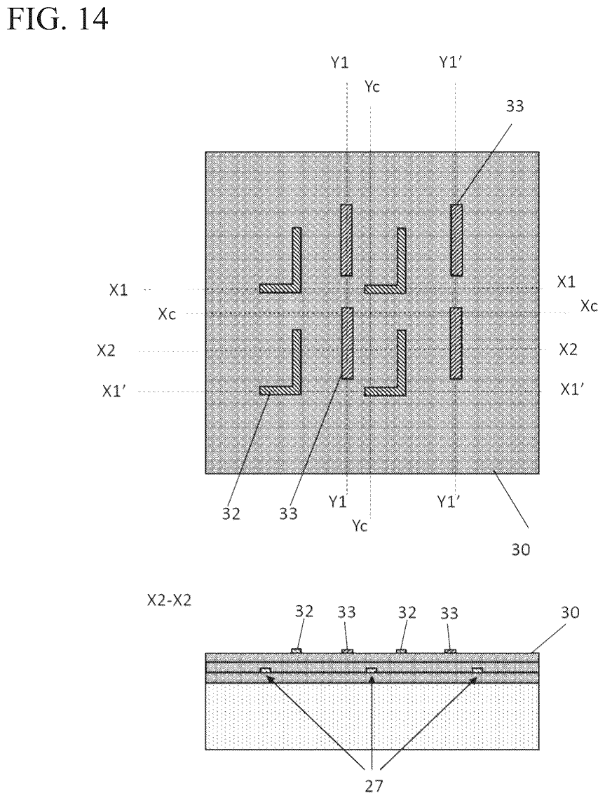

Next, as shown in FIG. 12, the contact holes 31a are filled with metal such as Ti/Au by a known method such as vapor deposition, and the first electrodes 32 connected to the vertical wirings 27 are formed, and at the same time, the contact holes 31b are filled, and the second electrodes 33 connected to the horizontal wiring 29 are formed. FIG. 13 shows the Xc-Xc cross section, and FIG. 14 shows the X2-X2 cross section. Referring to FIG. 14, it can be understood that the first electrode 32 and the second electrode 33 form a pair and function as electrodes of the CNT element. As a result, a part of the connection electrode 14R and the first branch electrode 12a, and a part of the connection electrode 14L and the second branch electrode 13a explained in FIG. 1 are formed.

The first electrode and the second electrode can be made using, for example, gold, platinum, or titanium alone or in combination. The electrode can be formed by, for example, vapor deposition, sputtering, or printing, although the method for producing the electrode is not particularly limited. The thickness of the first electrode and the second electrode can be adjusted as appropriate, but is preferably 10 nm to 1 mm, more preferably 50 nm to 1 μm. Further, the distance between the first and second electrodes in the substantially parallel portions is preferably 1 μm to 500 μm, and more preferably 5 to 200 μm for miniaturization.

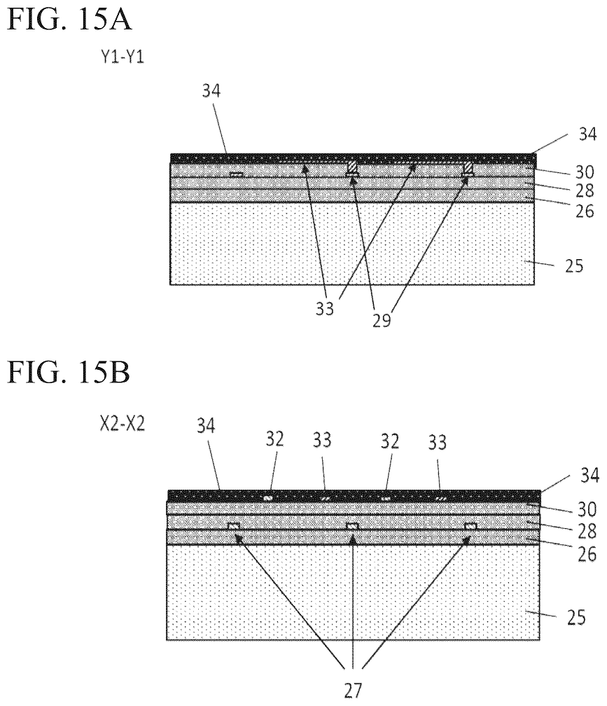

Next, a CNT film 34 is formed so as to span at least between the first electrode 32 and the second electrode 33. Namely, the CNT film 34 is in contact with at least a portion of the first electrode 32, covers between the first electrode 32 and the second electrode 33, and is in contact with at least a portion of the second electrode 33. FIG. 15A shows a Y1-Y1 cross section, and FIG. 15B shows an X2-X2 cross section. As a result, a CNT element and a bolometer element having “one layer of CNT film” are formed by the first electrode 32, the second electrode 33, and the CNT film 34 existing between them. A preferable thickness of the CNT film will be described later.

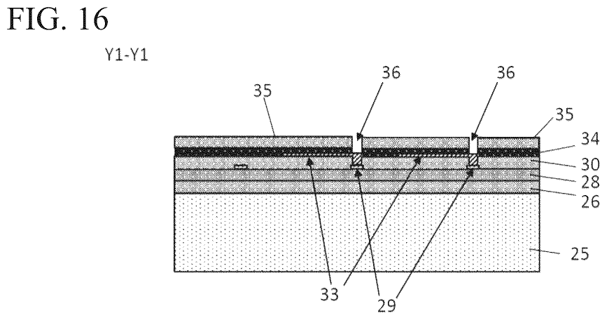

The following description will mainly be made using Y1-Y1 cross-sectional views. Now, FIG. 16 is referred. A silicon oxide film 35 is formed as an insulating film on the formed CNT film 34. This insulating film insulates between the CNT films. The material of the insulating film is not limited as long as it is an insulating material, but it is preferably a material that has high light absorption at the wavelength of the electromagnetic wave to be detected. Examples of the material of the insulating film include SiN, SiO₂, HfO₂, and the like. Among them, SiN and SiO₂ have high light absorption properties and can function as a light absorption film, and therefore they are advantageous when using the element of the present embodiment in a bolometer. The thickness of each insulating film is not particularly limited, but is 1 nm to 1 μm, preferably 5 nm to 100 nm.

Next, contact holes 36 (FIG. 16) are formed at the same position as the contact holes 31a and 31b (see FIG. 11) so that the first electrode 32 and the second electrode 33 are exposed. The method for forming the contact holes 36 is the same as that for forming the contact holes 31a and 31b described above, and it is preferable to remove the silicon oxide film and the CNT film at the same time using the first electrode 32 and the second electrode 33 as etching stoppers.

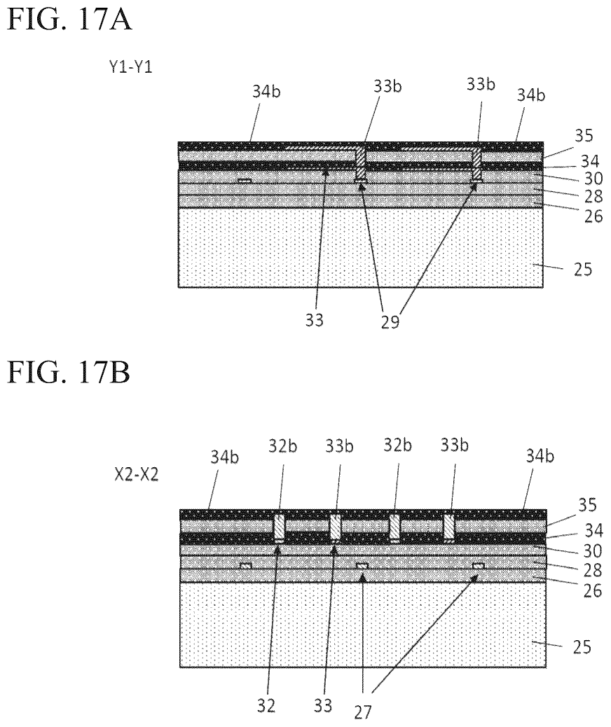

On the silicon oxide film 35 after forming the contact holes 36, a first electrode 32b and a second electrode 33b having the same pattern as in FIG. 12 are formed. A CNT film 34b is formed thereon in the same process as in FIGS. 15A and 15B. As a result, a structure in which two layers of CNT films are connected in parallel is formed, as shown in FIGS. 17A and 17B.

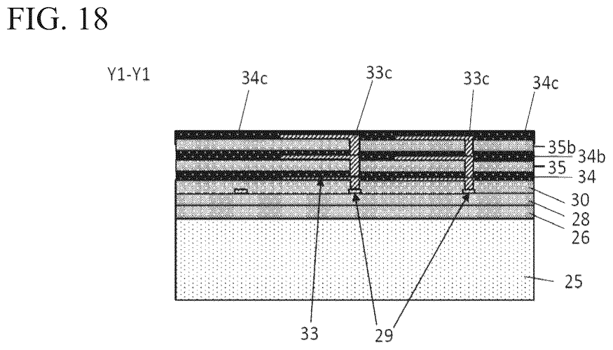

Furthermore, by similar process, a silicon oxide film 35b is formed, contact holes are formed, a first electrode 32c (not shown) and a second electrode 33c are formed, and then a CNT film 34c is formed. As shown in FIG. 18, the main part of the bolometer element having a structure in which three layers of CNT films are connected in parallel is completed.

A device having a structure in which CNT films are further stacked is manufactured by repeating required cycles of the steps of forming a silicon oxide film, forming contact holes, forming a first electrode and a second electrode, and forming a CNT film, taking these steps as one cycle. Preferably, a silicon oxide film is formed on the CNT film at the top of the bolometer element, so as to make the silicon oxide film to serve as a protective film too.

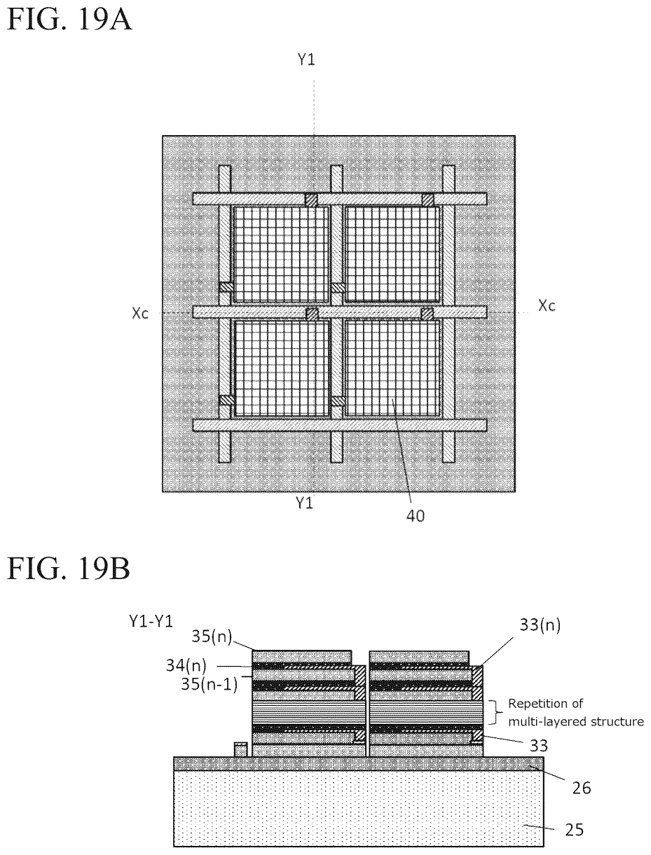

Finally, in order to separate the bolometer elements into four (2×2) bolometer elements, an area slightly smaller than the positions of the vertical wiring and horizontal wiring is protected with a mask 40, when viewed from above (plan view) as shown in FIG. 19A, and then etching is performed until the vertical wiring is exposed. Here, since the electrodes and wirings serve as etching stoppers, etching stops when the metals are exposed when viewed from above. Thereafter, the mask is removed, and four (2×2) integrated bolometer elements are completed, as shown in FIG. 19B. In one bolometer element, n-layer CNT films 34 are stacked with n−1 layer silicon oxide films 35 interposed therebetween. Since one first electrode 32 (not shown) and one second the second electrode 33, which is formed with predetermined distance from the first electrode 32, are electrically connected to one layer of CNT film 34, the n-layer CNT films are electrically connected in parallel.

### Modification of Embodiment 1

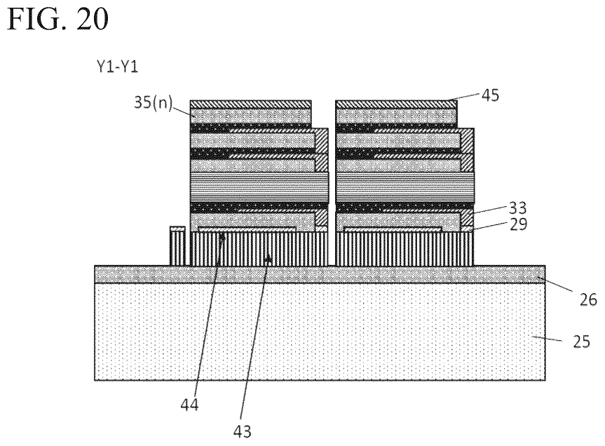

In the description of Embodiment 1, it was described that a heat insulating layer made of parylene or the like may be provided as an insulating film on the substrate surface instead of or in addition to the silicon oxide film 26. Furthermore, a heat insulating layer may be provided using parylene or the like instead of or in addition to the silicon oxide film between vertical and horizontal wiring and/or the silicon oxide film 26 above the horizontal wiring. FIG. 20 shows an example in which a heat insulating layer 43 is provided instead of the silicon oxide film 28 between the vertical wiring 27 and the horizontal wiring 29. By providing a heat insulating layer, heat conduction in the thickness direction of the element is suppressed, so that heat can be prevented from being transmitted to adjacent elements (pixels) through the substrate.

As a modification of Embodiment 1, a light reflective layer may be provided. The light reflecting layer can be formed at a position such as a lower part or an upper part of the light receiving part. As the material for the light reflection layer, any material used as a light reflection layer in a bolometer can be used without any limitation, and metals such as gold, silver, aluminum, etc. are generally used. For example, when forming a wiring layer (vertical wiring or horizontal wiring), it is preferable to pattern the same metal at the same time because it simplifies the process. FIG. 20 shows an example in which the light reflective layer 44 is formed at the same time as the horizontal wiring 29 is formed.

As a modification of the first embodiment, a protective film may be provided in addition to or in place of the uppermost silicon oxide film. As the protective film, any material used as a protective film in a bolometer can be used without restriction, but materials with high transparency in the wavelength range to be detected are preferable. Examples of such resins include, but are not limited to, parylene, acrylic resins such as PMMA, and PMMA anisole, epoxy resins, and Teflon (registered trademark) and the like. The thickness of the protective film may be, for example, 5 nm to 50 nm, although it depends on the material. FIG. 20 shows an example in which the light reflective layer 44 is formed at the same time as the horizontal wiring 29 is formed. FIG. 20 shows an example in which a protective film 45 is provided on the uppermost silicon oxide film 35(n).

Furthermore, a light absorption layer (light absorption film) may be provided, and for example, a silicon oxide film, a silicon nitride film, a polyimide coating film, a titanium nitride thin film, and the like are used. The light absorption layer can also serve as a protective film, or can be formed separately from the protective film. The thickness of the light absorption layer can be set as appropriate depending on the material, and can be, for example, 50 nm to 1 μm. A silicon oxide film deposited on the CNT film can also function as a light absorption layer.

### Embodiment 2

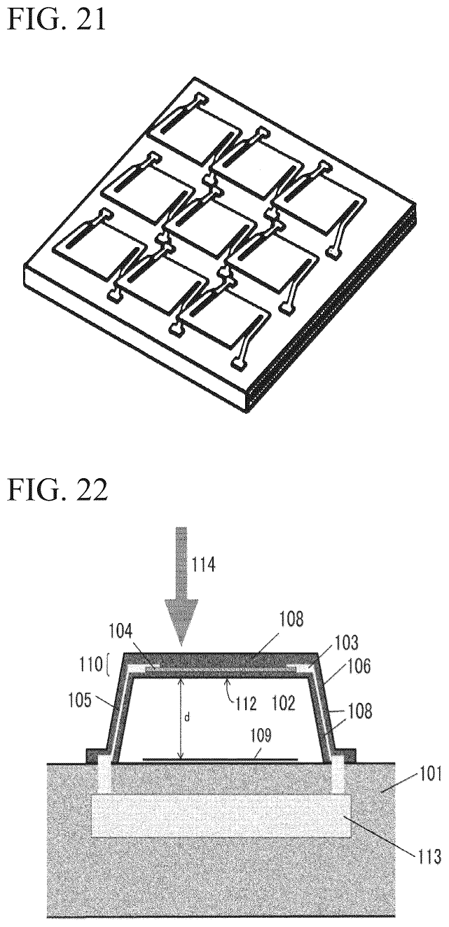

A CNT element can be used as a light receiving part of a diaphragm type bolometer. A diaphragm-type bolometer array is shown in FIG. 21 (perspective view), and a single element thereof is shown in FIG. 22. Note that FIG. 22 is a diagram schematically showing a cross section along a bent line including two support legs. The bolometer of the present embodiment includes a substrate 101 and an infrared detection section (light receiving section) 110 including a bolometer film 104, and the infrared detection section 110 is provided in the diaphragm portion 112 that is held on the substrate 101 by support legs 106 with a gap 102 interposed therebetween. Here, the “gap” means that a space exists between the infrared detection section and the substrate. Here, the insulating film (protective film 108, and the like) in the diaphragm portion 112 existing under the bolometer film 104 is regarded as an “insulating base material”, that is, it can be considered as an insulating base material on which a bolometer film (i.e., a stacked structure of a CNT film and an insulating film) is formed.

Two electrodes 103 opposing each other in contact with the bolometer film 104 are connected to the readout circuit section 113 via connection wirings 105 connected to each electrode. In the bolometer of the present embodiment, when incident light 114 enters the bolometer film 104 from above the bolometer, the intensity of infrared rays is detected by reading out the resistance change from the electrode 103 due to the temperature rise of the bolometer film 104.

Further, in the example shown in this figure, the top of the bolometer film 104 (CNT element) and the top and bottom of the wiring 105 are protected by a protective film 108. The protective film also functions as an insulating film, and the materials described in Embodiment 1 can be used in addition to a silicon oxide film and a silicon nitride film.

The bolometer of the present embodiment uses the CNT element of the present embodiment as an infrared detection section (light receiving section) 110 including a bolometer film 104. For the structure of the CNT element, for example, the structure described in Embodiment 1 can be applied as it is. In this case, the CNT element can have the same structure by considering that the protective film (particularly the silicon oxide film) below the bolometer film 104 corresponds to the silicon oxide film 26 described in the Embodiment 1.

The bolometer of the present embodiment may include a light reflecting layer 109 between the substrate 101 and the light receiving section 104.

Further, the bolometer of the present embodiment may include a light absorption layer above the light receiving portion, that is, on the side where light enters. The configuration described in the modification of Embodiment 1 can be adopted.

The bolometer of the present embodiment can be manufactured using a normal silicon MEMS (Micro Electro Mechanical Systems) process. In the MEMS process, first, an interlayer insulating film is formed by CVD on a semiconductor substrate 101 on which a readout circuit 113 composed of CMOS (complementary metal oxide semiconductor) transistors and the like is formed, and as an upper layer if necessary, a metal light-reflecting film 109, an interlayer insulating film, and a sacrificial layer are formed. Thereafter, a protective insulating film 108 is formed by the CVD method, and a light-receiving section, that is, the element of the present embodiment, and then, if necessary, a light-absorbing layer are formed thereon. Finally, the sacrificial layer is removed by etching to form a gap 102 to obtain a cell with a diaphragm structure.

The height d of the gap can be appropriately set in consideration of heat insulation properties, and the like, but in the case of a bolometer including the light reflective layer 109, it is also preferable to determine the height d of the gap in consideration of the wavelength of light. From the viewpoint of ease of manufacture, the height d of the gap is preferably 0.5 μm or more.

The insulation between the infrared detection unit and the substrate can also be improved by vacuum packaging the entire element and keeping the gap in vacuum.

### <Carbon Nanotube Film)>

The carbon nanotube film (CNT film) used in the bolometer element of the present embodiment described above will be explained in more detail.

As the carbon nanotube films, single-walled, double-walled, and multi-walled carbon nanotubes may be used, but when semiconducting carbon nanotubes are separated, single-walled or few-walled (for example, double-walled or triple-walled) carbon nanotubes are preferred, and single-walled carbon nanotubes are more preferred. The carbon nanotubes preferably comprise single-walled carbon nanotubes in an amount of 80% by mass or more, and more preferably 90% by mass or more (including 100% by mass).

The diameter of the carbon nanotubes is preferably from 0.6 to 1.5 nm, more preferably 0.6 nm to 1.2 nm, and further preferably 0.7 to 1.1 nm, from the viewpoint of increasing the band gap to improve TCR. In one embodiment, the diameter of 1 nm or less may be particularly preferred in some cases. When the diameter is 0.6 nm or more, the manufacture of carbon nanotubes becomes much easier. When the diameter is 1.5 nm or less, the band gap is easily maintained in an appropriate range and a high TCR can be obtained.

As used herein, the diameter of the carbon nanotubes means that when the carbon nanotube film is observed using an atomic force microscope (AFM) and the diameter thereof is measured at about 100 positions, 60% or more, preferably 70% or more, optionally preferably 80% or more, more preferably 100% thereof is within a range of 0.6 to 1.5 nm. It is preferred that 60% or more, preferably 70% or more, optionally preferably 80% or more, and more preferably 100% thereof be within a range of 0.6 to 1.2 nm, and further preferably within a range of 0.7 to 1.1 nm. In one embodiment, 60% or more, preferably 70% or more, optionally preferably 80% or more, and more preferably 100% thereof is within a range of 0.6 to 1 nm.

The length of the carbon nanotubes is preferably from 100 nm to 5 μm because dispersion is easy and application properties are excellent. Also, from the viewpoint of conductivity of the carbon nanotubes, the length is preferably 100 nm or more. When the length is 5 μm or less, aggregation at the time of forming a layer is easily suppressed. The length of the carbon nanotubes is more preferably 500 nm to 3 μm, and further preferably 700 nm to 1.5 μm.

As used herein, the length of the carbon nanotubes means that, when at least 100 carbon nanotubes are observed using an atomic force microscope (AFM) and enumerated to measure the distribution of the length of the carbon nanotubes, 60% or more in terms of number ratio, preferably 70% or more, optionally preferably 80% or more, and more preferably 100% thereof is within a range of 100 nm to 5 μm. It is preferred that 60% or more, preferably 70% or more, optionally preferably 80% or more, and more preferably 100% thereof be within a range of 500 nm to 3 μm, and it is more preferred that 60% or more, preferably 70% or more, optionally preferably 80% or more, and more preferably 100% thereof be within a range of 700 nm to 1.5 μm.

When the diameter and length of the carbon nanotubes are within the above range, the influence of semiconductive properties becomes large and a large current value can also be obtained, and thus, a high TCR value is likely to be obtained when the carbon nanotubes are used as a bolometer film.

For the bolometer film, semiconducting carbon nanotubes having a large band gap and carrier mobility are preferably used. The content of the semiconducting carbon nanotubes, preferably single-walled semiconducting carbon nanotubes in carbon nanotubes is preferably 80% by mass or more, and in particular, preferably 90% by mass or more, more preferably 95% by mass or more, and further preferably 99% by mass or more (the upper limit may be 100% by mass).

If the carbon nanotube film is too thick, the contact electrode formed from above by vapor deposition and the like may not make sufficient contact with the carbon nanotubes existing in the lower part of the carbon nanotube film, and the effective resistance value may become high. In the element of the present embodiment, since the carbon nanotubes and the insulating films are stacked and contact electrodes are connected to each carbon nanotube film, low resistance can be achieved.

The thickness of the carbon nanotube film is not limited, in the range of, for example, 1 nm or more, for example a few nm to 10 μm, preferably 10 nm to 10 μm, more preferably 50 nm to 1 μm. In one embodiment, it is preferably 20 nm to 500 nm, more preferably 50 nm to 200 nm or more.

When the thickness of the carbon nanotube film is 1 nm or more, a good light absorption rate can be achieved.

Further, it is preferable that the thickness of the carbon nanotube film is 1 μm or less, preferably 500 nm or less, from the viewpoint of simplifying the manufacturing method.

Also, when the thickness of the carbon nanotube film is in the range of 10 nm to 1 μm as described above, it is also preferable that printing techniques can be suitably applied to the manufacturing method of the carbon nanotube film.

The thickness of the carbon nanotube film may be appropriately set depending on the presence or absence of a light reflection layer, a light absorption layer, and the like.

The thickness of the carbon nanotube film can be determined as an average value of the thickness of the carbon nanotube film measured at arbitrary 10 positions.

The density of the carbon nanotube film is, for example, 0.3 g/cm³ or more, preferably 0.5 g/cm³ or more, more preferably 0.8 g/cm³ or more, further more preferably 1.1 g/cm³ or more. The upper limit thereof is not particularly limited, but can be the upper limit of the true density of the carbon nanotube used (for example, about 1.4 g/cm³).

When the density of the carbon nanotube film is 0.3 g/cm³ or more, a good light absorbing rate can be achieved.

The density of the carbon nanotube film can be calculated from weight, area, and the thickness obtained as above of the carbon nanotube film.

In addition to the above-mentioned components described above, negative thermal expansion materials described later, ionic conductors (surfactants, ammonium salts, inorganic salts), resins, organic binding agents, and the like may also be appropriately used in the carbon nanotube film.

The content of carbon nanotubes in the carbon nanotube film is preferably at least the amount required for percolation of carbon nanotubes so that electric current flows, and can be appropriately selected depending on the materials to be mixed. For example, the content of carbon nanotubes is preferably 0.1% by mass or more, more preferably 1% by mass or more, and in some cases, it may be, for example, 30% by mass or more, furthermore 50% by mass or more, 60% by mass or more, 70% by mass, 80% by mass or more, 90% by mass or more, or 95% or more, based on the total mass of the carbon nanotube film in each case.

A carbon nanotube film can be manufactured by a known manufacturing method. As an example, a carbon nanotube dispersion liquid is prepared by mixing a carbon nanotube mixture containing metallic carbon nanotubes and semiconducting carbon nanotubes with a nonionic surfactant in a dispersion medium. If necessary, it can be cut into a desired length by ultrasonication during dispersion. After that, the semiconducting carbon nanotubes can be separated by carrier-free electrophoresis using electric field induced layer formation method (ELF method: for example, see K. Ihara et al. J. Phys. Chem. C. 2011, 115, 22827-22832, Japanese Patent No. 5717233, these documents are herein incorporated by reference).

Through the aforementioned dispersion and cutting step and separation step of the carbon nanotubes, a dispersion liquid in which the semiconducting carbon nanotubes having the desired diameter and length are concentrated can be obtained. As used herein, the carbon nanotube dispersion liquid in which semiconducting carbon nanotubes are concentrated may be referred to as the “semiconducting carbon nanotube dispersion liquid”. The semiconducting carbon nanotube dispersion liquid obtained by the separation step comprises semiconducting carbon nanotubes generally preferably 80% by mass or more in the total amount of carbon nanotubes, and it is particularly preferably 90% by mass or more, more preferably 95% by mass or more, further preferably 99% by mass or more (the upper limit may be 100% by mass). The separation tendency of the metallic and semiconducting carbon nanotubes can be analysed by microscopic Raman spectroscopy and ultraviolet-visible near-infrared spectroscopy.

The concentration of the surfactant in the carbon nanotube dispersion liquid may be appropriately controlled. The concentration of the surfactant in the carbon nanotube dispersion liquid is preferably from the critical micelle concentration to about 5% by mass, more preferably, 0.001% by mass to 3% by mass, and particularly preferably 0.01 to 1% by mass to suppress the reaggregation after application and the like.

The semiconducting carbon nanotube dispersion liquid obtained through the aforementioned steps is applied on an insulating base material or an insulating layer and dried, and then a heat treatment is optionally performed, so that a carbon nanotube layer is formed.

The method for applying the semiconducting carbon nanotube dispersion liquid to an insulating base material or an insulating layer is not particularly limited, and examples thereof include dropping method, spin coating, printing, inkjet, spray coating, dip coating, and the like. From the viewpoint of reducing the manufacturing cost, a printing method is preferred. The printing methods can include application (dispenser, inkjet or the like), transferring (microcontact print, gravure printing, or the like) and the like.

The surface of the insulating base material or the insulating film to which the semiconducting carbon nanotube dispersion is applied is preferably subjected to surface treatment. Examples of surface treatment agents include a compound having a partial structure having a first moiety selected from the group consisting of alkoxysilyl group (SiOR), SiOH, hydrophobic moiety, hydrophobic group and the like and a second moiety selected from the group consisting of an amino group such as primary amino group (—NH₂), secondary amino group (—NHR), tertiary amino group (—NR₁R₂), ammonium group (—NH₄), epoxy group and the like.

Examples thereof include silane coupling agents (aminosilane compound) having an amino group and an alkoxysilyl group such as 3-aminopropyltrimethoxysilane, 3-aminopropylmethyltriethoxysilane, 3-aminopropylmethyltrimethoxysilane, 3-aminopropyltriethoxysilane (APTES), 3-(2-aminoethyl)aminopropyltrimethoxysilane, N-(2-aminoethyl)-3-aminopropyltrimethoxysilane, N-2-(aminoethyl)-3-aminopropylmethyltrimethoxysilane, and N-(2-aminoethyl)-3-aminopropylmethyldimethoxysilane; and silane coupling agents having an epoxy group and an alkoxysilyl group such as 3-glycidoxypropyltrimethoxysilane, 3-glycidoxypropyltriethoxysilane, 3-glycidoxypropylmethyldimethoxysilane, 3-glycidoxypropylmethyldiethoxysilane, 2-(3,4-epoxycyclohexyl)ethyltrimethoxysilane, 3-glycidoxypropyldiethoxysilane, and triethoxy(3-glycidyloxypropyl)silane. In particular, a silane coupling agent having an amino group (aminosilane compound) is preferred because it has good bonding properties with carbon nanotubes.

In the present embodiment, it is preferable that the surfaces of the insulating base materials and the insulating films on which the CNT films are formed are subjected to surface treatment in all layers in the multi-layered structure. However, it is also possible that only some layers of the insulating base materials and the insulating films are surface-treated.

The semiconducting carbon nanotubes dispersion liquid applied on a desired base material may be subjected to a heat treatment to remove the surfactant and the solvent. The temperature of the heat treatment may be appropriately set as long as it is equal to or higher than the decomposition temperature of the surfactant, and it is preferably 150 to 500° C., and more preferably 200 to 500° C., for example 200 to 400° C. A temperature of 200° C. or more is preferred because the remaining of the decomposition product of the surfactant can be easily suppressed. A temperature of 500° C. or less, for example 400° C. or less is preferred because the change in the quality of the substrate or other components can be suppressed. Also, the decomposition of carbon nanotubes, the change in size, the leaving of functional groups, and the like can be suppressed.

### (Negative Thermal Expansion Material)

In an embodiment, the carbon nanotube films can comprise a negative thermal expansion material in addition to the carbon nanotubes.

The carbon nanotube film according to the present embodiment is a carbon nanotube composite material in which a negative thermal expansion material is dispersed in a carbon nanotube aggregate having a three-dimensional mesh structure that forms a network structure formed of dispersed carbon nanotubes intertwined with each other into an aggregate. In such a three-dimensional electrically conductive network formed of carbon nanotubes, the carbon nanotubes are not necessarily all connected to each other to contribute to electric conductivity in the carbon nanotube film, but part of the carbon nanotubes does not contribute to the electrical conduction mechanism. These unconnected carbon nanotubes build a new electrically conductive path resulting from the effect of reduction in the volume of the negative thermal expansion material exhibited by an increase in temperature. Or, the effect of reduction in the volume further increases the contact area between the carbon nanotubes, and moreover, the number of electrically conductive paths also increases. As a result, a larger increase in current occurs as the temperature increases, resulting in an improvement in a TCR value. That is, the negative thermal expansion material mixed with the semiconducting carbon nanotubes shrinks as the temperature rises, creating an additional network of carbon nanotubes previously separate from each other, resulting in an increase in the number of electrically conductive paths, whereby a greater amount of current flows. Furthermore, in an embodiment, using a negative thermal expansion material having resistance greater than that of the semiconducting carbon nanotubes allows more efficient formation of electrically conductive paths formed of the semiconducting carbon nanotubes.

In the present specification, the negative thermal expansion material means a material that has a negative coefficient of thermal expansion and contracts as the temperature rises. Examples of the negative thermal expansion material include a material having a coefficient of linear thermal expansion ΔL/L ((length after expansion−length before expansion)/length before expansion) per temperature difference of 1K preferably ranging from −1×10⁻⁶/K to −1×10⁻³/K, more preferably from −1×10⁻⁵/K to −1×10⁻³/K, in any temperature range from −100 to +200° C., for example, the range from −100 to +100° C., preferably in the temperature range over which the bolometer is used, for example, at least in the range from −50 to 100° C.

The coefficient of thermal expansion can be measured in accordance, for example, with JIS Z 2285 (method for measuring coefficient of linear expansion of metallic materials) or JIS R 1618 (method for measuring thermal expansion of fine ceramics based on thermo-mechanical analysis).

In an embodiment, the negative thermal expansion material is preferably a material that exhibits sufficient negative thermal expansion in the environment in which the bolometer is used. The temperatures of the environment in which the bolometer is used range, for example, from −350° C. to 100° C., preferably from −40° C. to 80° C., more preferably in some cases from 20° C. to 30° C., for example, from 21° C. to 30° C.

The humidity in the environment in which the bolometer is used, for example, in a case where the bolometer is used in a structure in which the bolometer part is exposed to the atmosphere, may be the ambient humidity, preferably, for example, 75% RH or lower. When the bolometer is vacuum-packaged or used in a structure in which the package is filled with an inert gas, the humidity is preferably, for example, 5% RH or lower, and may not fall within the range described above depending on the degree of vacuum and other factors. From the viewpoint of long-term stability of the device, lower humidity is preferable, so that the lower limit is not limited to a specific value in either case, and the humidity is 0% RH or higher, for example, higher than 0% RH.

The resistivity of the negative thermal expansion material described above is not limited to a specific value, and can range from 10⁻¹ Ωcm to 10⁸ Ωcm, preferably from 1 Ωcm to 10⁸ Ωcm, more preferably from 10 Ωcm to 10⁷ Ωcm and further more preferably from 10² Ωcm to 10⁶ Ωcm, in any temperature range from −100 to +100° C., preferably at the temperature at which the bolometer is used, for example, room temperature (about 23° C.). The resistivity can be measured in accordance with standard methods, for example, JIS K 7194 and JIS K 6911.

In the present specification, the negative thermal expansion material may include oxides, nitrides, sulfides or multi-element compounds containing one or two or more of Li, Al, Fe, Ni, Co, Mn, Bi, La, Cu, Sn, Zn, V, Zr, Pb, Sm, Y, W, Si, P, Ru, Ti, Ge, Ca, Ga, Cr, Cd, but not limited thereto. A mixture of two or more compounds may be used.

The negative thermal expansion material may include, but not limited thereto, vanadium oxides, β-eucryptite, bismuth-nickel oxides, zirconium tungstate, ruthenium oxides, manganese nitrides, lead titanate, samarium monosulfide and others (including those in which one or more of the elements of these compounds have been replaced by the above elements). For example, LiAlSiO₄, ZrW₂O₈, Zr₂WO₄(PO₄)₂, BiNi_{0.85}Fe_{0.15}O₃, Bi_{0.95}La_{0.05}NiO₃, Pb_{0.76}La_{0.04}Bi_{0.20}VO₃, Sm_{0.78}Y_{0.22}S, Cu_{1.8}Zn_{0.2}V₂O₇, Cu₂V₂O₇, 0.4PbTiO₃-0.6BiFeO₃, MnCo_{0.98}Cr_{0.02}Ge, Ca₂RuO_{3.74}, Mn₃Ga_{0.7}Ge_{0.3}N_{0.88}C_{0.12}, Cd(CN)₂·xCCl₄, LaFe_{10.5}Co_{1.0}Si_{1.5}, Ca₂RuO₄, Mn_{3.27}Zn_{0.45}Sn_{0.28}N, Mn₃Ga_{0.9}Sn_{0.1}N_{0.9}, Mn₃ZnN are suitable.

In one embodiment, oxides, nitrides, and sulfides are preferable among the negative thermal expansion materials, from the view point of ease of synthesis and availability.

In the present specification, the size of the negative thermal expansion material can be selected as appropriate. Preferably, it is 10 nm to 100 μm, more preferably 15 nm to 10 μm, and in some cases, it is also preferred to be from 50 nm to 5 μm.

The form of the negative thermal expansion material is not particularly limited, but may be, for example, spherical, needle, rod, plate, fiber, scale and the like, with spherical being preferred in terms of film formability.

The amount of negative thermal expansion material in the carbon nanotube film can be selected as appropriate, but it is preferable that it is contained in an amount of 1 to 99% by mass, based on the total mass of the carbon nanotube film, with 1 to 70% by mass being more preferable, for example, 1 to 50% by mass, in some cases 10 to 50% by mass, and optionally 40% by mass or less may also be preferred.

In addition to the carbon nanotubes and the negative thermal expansion material as an optional component, the carbon nanotube film may also comprise a binder and, if desired, other components, but it is preferred that the total mass of the carbon nanotubes and the negative thermal expansion material is 70% by mass or more, more preferably 90% by mass or more, and even more preferably 95% by mass or more, based on the mass of the carbon nanotube film.

The carbon nanotube film comprising carbon nanotubes and negative thermal expansion materials can be produced by using a dispersion liquid in which a carbon nanotube dispersion is added with the negative thermal expansion materials and, if necessary, binding agents and the like in the above-described method of producing a carbon nanotube film using a carbon nanotube dispersion.

Since the element according to the present embodiment uses a light-receiving section in which carbon nanotube films and insulating films are stacked into a multi-layer form, and thus has a higher light absorption rate than a conventional bolometer. Therefore, in one embodiment, it is also preferable to omit one or both of a light reflection layer and a light absorption layer. This makes it possible to further simplify the element structure and reduce the cost of the manufacturing process.

### <Bolometer Array>

As shown in Embodiments 1 and 2, the CNT element of the present embodiment can be applied to a bolometer array. In such a structure, an electric signal is applied to the vertical wiring and horizontal wiring corresponding to each cell, and the resistance change of the cell is read out. By sequentially reading out the resistance changes of all cells, a two-dimensional image sensor can be constructed.

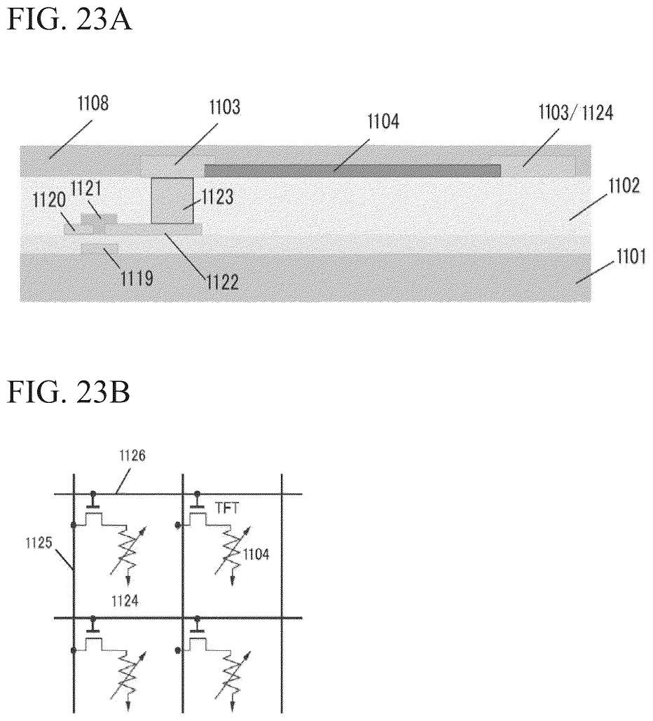

A transistor array is also preferably applied to the array sensor according to the present embodiment. The application of a transistor array makes possible high-speed scanning. In the case of the bolometer cell of Embodiment 1, it is preferable to apply a TFT (thin film transistor) array. An example of a TFT array is shown in FIGS. 23A and 23B. In the TFT array shown in FIG. 23A, gate electrode 1119 is placed on substrate 1101, and a source electrode 1120, a semiconductor layer 1123, and a drain electrode 1122 are formed on the upper layer thereof with an insulating layer therebetween. Upper thereof, the light-receiving section of the present embodiment having a multi-layered structure including the carbon nanotube films and the insulating films is formed. Drain electrode 1122 is connected to contact electrode 1103, which is formed in contact with the carbon nanotube film 1104, through via 1123 that extends through heat insulating layer 1102. The other electrode 1103 is connected to common electrode 1124. FIG. 23B shows the two-dimensional arrangement of the pixel circuit of this TFT array.

As the form of the transistor array, a diaphragm-type bolometer cell as in Embodiment 2 is also possible, and forms used in this technical field can be applied without particular limitation, such as building a transistor array as part of the readout circuit section 113.

The bolometer of the present embodiment detects temperature using the temperature dependence of electrical resistance due to light irradiation. Therefore, it can be similarly used in other frequency ranges as long as the temperature changes due to light irradiation. The bolometer of the present embodiment using a carbon nanotube film in the light receiving section can be particularly suitably used for detecting electromagnetic waves having a wavelength of 0.7 μm to 1 mm. Electromagnetic waves included in the wavelength range include infrared rays and terahertz waves.

The bolometer of the present embodiment is preferably an infrared sensor.

Although the embodiment in which the element of the present embodiment is used in a bolometer has been described above, the element of the present embodiment can be used in thin film transistors, temperature sensors, pressure-sensitive sensors, strain sensors, and the like. in addition to bolometers.

Some or all of the above embodiments may also be described as in the Supplementary notes below, but the disclosures of the present application are not limited to the Supplementary notes below.

### (Supplementary Note 1)

A carbon nanotube element comprising:
a multi-layered structure in which a plurality of carbon nanotube films and one or more insulating film(s) are stacked so that the insulating film(s) insulates between the carbon nanotube films, and
a first electrode and a second electrode arranged with a distance,
wherein each carbon nanotube film in the multi-layered structure is electrically connected to the first electrode and the second electrode, and the carbon nanotube films are connected in parallel to each other between the first electrode and the second electrode.

### (Supplementary Note 2)

The carbon nanotube element according to Supplementary note 1, wherein the first electrode comprises a plurality of first branch electrodes, the second electrode comprises a plurality of second branch electrodes, wherein the first electrode is electricity connected to each carbon nanotube film by the first branch electrodes, and the second electrode is electrically connected to each carbon nanotube film by the second branch electrodes.

### (Supplementary Note 3)

The carbon nanotube element according to Supplementary note 1, wherein the multi-layered structure is formed on an insulating base material.

### (Supplementary Note 4)

The carbon nanotube element according to Supplementary note 1, wherein the carbon nanotube film comprises semiconducting carbon nanotubes in an amount of 90% by mass or more based on the total amount of carbon nanotubes.

### (Supplementary Note 5)

The carbon nanotube element according to Supplementary note 1, wherein 60% or more of the carbon nanotubes included in the carbon nanotube film have a diameter in the range of 0.6 to 1.5 nm and a length in the range of 100 nm to 5 μm.

### (Supplementary Note 6)

The carbon nanotube element according to Supplementary note 1, wherein the carbon nanotube film includes a negative thermal expansion material.

### (Supplementary Note 7)

The carbon nanotube element according to Supplementary note 1, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

### (Supplementary Note 8)

A bolometer comprising the carbon nanotube element according to Supplementary note 1 as a light receiving section.

### (Supplementary Note 9)

A method for manufacturing a carbon nanotube element having n-layer carbon nanotube films, the method comprising:
performing following steps (a₁), (b₁) and (c₁) in this order to form a structure having a first layer of carbon nanotube film;
repeating following steps (aₖ), (bₖ) and (cₖ) in this order from k=2 to n to form structures having a second layer carbon nanotube film to an n-th layer carbon nanotube film;
   wherein
(a₁): providing an insulating base material,
(b₁): forming a first branch electrode and a second branch electrode with a distance on the insulating base material provided in step (a₁),
(c₁): forming a carbon nanotube film in contact with the first branch electrode and the second branch electrode formed in step (b1),
(aₖ): forming an insulating film on a first branch electrode, a second branch electrode, and a carbon nanotube film formed in step (bₖ₋₁) and step (cₖ₋₁), respectively,
(bₖ): forming holes in the insulating film formed in step (aₖ) to reach the first branch electrode and the second branch electrode formed in step (bₖ₋₁), and thereafter filling the holes and forming a first branch electrode and a second branch electrode opposing each other with a distance on the insulating film at the same time using an electrode material, and
(cₖ): forming a carbon nanotube film in contact with the first branch electrode and the second branch electrode formed in step (bₖ).

### (Supplementary Note 10)

A method for manufacturing a carbon nanotube element having n-layer carbon nanotube films, the method comprising:
performing following steps (a₁), (c²₁) and (b²₁) in this order to form a structure having a first layer of carbon nanotube film;
repeating following steps (aₖ), (c²ₖ) and (b²ₖ) in this order from k=2 to n to form structures having a second layer carbon nanotube film to an n-th layer carbon nanotube film;
   wherein
(a₁): providing an insulating base material,
(c²₁): forming a carbon nanotube film on the insulating base material provided in step (a₁),
(b²₁): forming a first branch electrode and a second branch electrode with a distance so as to be in contact with the carbon nanotube film formed in step (c²₁),
(aₖ): forming an insulating film on a carbon nanotube film and a first branch electrode and a second branch electrode formed in step (c²ₖ₋₁) and step (b²ₖ₋₁), respectively,
(c²ₖ): forming a carbon nanotube film on the insulating film formed in step (aₖ), and
(b²ₖ): forming holes in the insulating film formed in step (aₖ) to reach the first branch electrode and the second branch electrode formed in step (b²ₖ₋₁), and thereafter filling the holes and forming a first branch electrode and a second branch electrode opposing each other with a distance so as to be in contact with the carbon nanotube film formed in step (c²ₖ) at the same time using an electrode material.

### (Supplementary Note 11)

The method for manufacturing a carbon nanotube element according to Supplementary note 9, further comprising the step of forming a film having at least one function selected from the group consisting of an insulating film, a protective film, and a light absorption film on the n-th carbon nanotube film formed in Supplementary note 9.

### (Supplementary Note 12)

The method for manufacturing a carbon nanotube element according to Supplementary note 9, wherein the carbon nanotube film comprises semiconducting carbon nanotubes in an amount of 90% by mass or more based on the total amount of carbon nanotubes.

### (Supplementary Note 13)

The method for manufacturing a carbon nanotube element according to Supplementary note 9, wherein 60% or more of the carbon nanotubes included in the carbon nanotube film have a diameter in the range of 0.6 to 1.5 nm and a length in the range of 100 nm to 5 μm.

### (Supplementary Note 14)

The method for manufacturing a carbon nanotube element according to Supplementary note 9, wherein the carbon nanotube film includes a negative thermal expansion material.

### (Supplementary Note 15)

The method for manufacturing a carbon nanotube element according to Supplementary note 9, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

### (Supplementary Note 16)

The method for manufacturing a carbon nanotube element according to Supplementary note 10, further comprising the step of forming a film having at least one function selected from the group consisting of an insulating film, a protective film, and a light absorption film on the n-th carbon nanotube film formed in Supplementary note 10.

### (Supplementary Note 17)

The method for manufacturing a carbon nanotube element according to Supplementary note 10, wherein the carbon nanotube film comprises semiconducting carbon nanotubes in an amount of 90% by mass or more based on the total amount of carbon nanotubes.

### (Supplementary Note 18)

The method for manufacturing a carbon nanotube element according to Supplementary note 10, wherein 60% or more of the carbon nanotubes included in the carbon nanotube film have a diameter in the range of 0.6 to 1.5 nm and a length in the range of 100 nm to 5 μm.

### (Supplementary Note 19)

The method for manufacturing a carbon nanotube element according to Supplementary note 10, wherein the carbon nanotube film includes a negative thermal expansion material.

### (Supplementary Note 20)

The method for manufacturing a carbon nanotube element according to Supplementary note 10, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

### INDUSTRIAL APPLICABILITY

The carbon nanotube element according to the present embodiment can be used for a bolometer, a thin film transistor, a temperature sensor, a pressure sensor, a strain sensor, and the like.

### EXPLANATION OF REFERENCE

1 Carbon tube (CNT) element
2 Multi-layered structure
10a to 10e Semiconductor type carbon nanotube film (CNT film)
11a to 11e Insulating film
12 First electrode
13 Second electrode
12a-12e First branch electrode
13a-13e Second branch electrode
15 Insulating base material
14R connection electrode
14L connection electrode

1. A carbon nanotube element comprising:
a multi-layered structure in which a plurality of carbon nanotube films and one or more insulating film(s) are stacked so that the insulating film(s) insulates between the carbon nanotube films, and
a first electrode and a second electrode arranged with a distance,
wherein each carbon nanotube film in the multi-layered structure is electrically connected to the first electrode and the second electrode, and the carbon nanotube films are connected in parallel to each other between the first electrode and the second electrode.

2. The carbon nanotube element according to claim 1, wherein the first electrode comprises a plurality of first branch electrodes, the second electrode comprises a plurality of second branch electrodes, wherein the first electrode is electricity connected to each carbon nanotube film by the first branch electrodes, and the second electrode is electrically connected to each carbon nanotube film by the second branch electrodes.

3. The carbon nanotube element according to claim 1, wherein the multi-layered structure is formed on an insulating base material.

4. The carbon nanotube element according to claim 1, wherein the carbon nanotube film comprises semiconducting carbon nanotubes in an amount of 90% by mass or more based on the total amount of carbon nanotubes.

5. The carbon nanotube element according to claim 1, wherein 60% or more of the carbon nanotubes included in the carbon nanotube film have a diameter in the range of 0.6 to 1.5 nm and a length in the range of 100 nm to 5 μm.

6. The carbon nanotube element according to claim 1, wherein the carbon nanotube film includes a negative thermal expansion material.

7. The carbon nanotube element according to claim 1, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

8. A method for manufacturing a carbon nanotube element having n-layer carbon nanotube films, the method comprising:
performing following steps (a₁), (b₁) and (c₁) in this order to form a structure having a first layer of carbon nanotube film;
repeating following steps (aₖ), (bₖ) and (cₖ) in this order from k=2 to n to form structures having a second layer carbon nanotube film to an n-th layer carbon nanotube film;
wherein
(a₁): providing an insulating base material,
(b₁): forming a first branch electrode and a second branch electrode with a distance on the insulating base material provided in step (a₁),
(c₁): forming a carbon nanotube film in contact with the first branch electrode and the second branch electrode formed in step (b1),
(aₖ): forming an insulating film on a first branch electrode, a second branch electrode, and a carbon nanotube film formed in step (bₖ₋₁) and step (cₖ₋₁), respectively,
(bₖ): forming holes in the insulating film formed in step (aₖ) to reach the first branch electrode and the second branch electrode formed in step (bₖ₋₁), and thereafter filling the holes and forming a first branch electrode and a second branch electrode opposing each other with a distance on the insulating film at the same time using an electrode material, and
(cₖ): forming a carbon nanotube film in contact with the first branch electrode and the second branch electrode formed in step (bₖ).

9. A method for manufacturing a carbon nanotube element having n-layer carbon nanotube films, the method comprising:
performing following steps (a₁), (c²₁) and (b²₁) in this order to form a structure having a first layer of carbon nanotube film;
repeating following steps (aₖ), (c²ₖ) and (b²ₖ) in this order from k=2 to n to form structures having a second layer carbon nanotube film to an n-th layer carbon nanotube film;
wherein
(a₁): providing an insulating base material,
(c²₁): forming a carbon nanotube film on the insulating base material provided in step (a₁),
(b²₁): forming a first branch electrode and a second branch electrode with a distance so as to be in contact with the carbon nanotube film formed in step (c²₁),
(aₖ): forming an insulating film on a carbon nanotube film and a first branch electrode and a second branch electrode formed in step (c²ₖ₋₁) and step (b²ₖ₋₁), respectively,
(c²ₖ): forming a carbon nanotube film on the insulating film formed in step (aₖ), and
(b²ₖ): forming holes in the insulating film formed in step (aₖ) to reach the first branch electrode and the second branch electrode formed in step (b²ₖ₋₁), and thereafter filling the holes and forming a first branch electrode and a second branch electrode opposing each other with a distance so as to be in contact with the carbon nanotube film formed in step (c²ₖ) at the same time using an electrode material.

10. The method for manufacturing a carbon nanotube element according to claim 8, further comprising the step of forming a film having at least one function selected from the group consisting of an insulating film, a protective film, and a light absorption film on the n-th carbon nanotube film formed in claim 8.

11. The method for manufacturing a carbon nanotube element according to claim 8, wherein the carbon nanotube film comprises semiconducting carbon nanotubes in an amount of 90% by mass or more based on the total amount of carbon nanotubes.

12. The method for manufacturing a carbon nanotube element according to claim 8, wherein 60% or more of the carbon nanotubes included in the carbon nanotube film have a diameter in the range of 0.6 to 1.5 nm and a length in the range of 100 nm to 5 μm.

13. The method for manufacturing a carbon nanotube element according to claim 8, wherein the carbon nanotube film includes a negative thermal expansion material.

14. The method for manufacturing a carbon nanotube element according to claim 8, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

15. The method for manufacturing a carbon nanotube element according to claim 9, further comprising the step of forming a film having at least one function selected from the group consisting of an insulating film, a protective film, and a light absorption film on the n-th carbon nanotube film formed in claim 9.

16. The method for manufacturing a carbon nanotube element according to claim 9, wherein the carbon nanotube film comprises semiconducting carbon nanotubes in an amount of 90% by mass or more based on the total amount of carbon nanotubes.

17. The method for manufacturing a carbon nanotube element according to claim 9, wherein 60% or more of the carbon nanotubes included in the carbon nanotube film have a diameter in the range of 0.6 to 1.5 nm and a length in the range of 100 nm to 5 μm.

18. The method for manufacturing a carbon nanotube element according to claim 9, wherein the carbon nanotube film includes a negative thermal expansion material.

19. The method for manufacturing a carbon nanotube element according to claim 9, wherein the negative thermal expansion material is oxide, nitride, sulfide, or multi-element compound, each comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.
